(19) United States
(12) Patent Application Publication
(10) Pub. No.: US 2007/0201527 A1
(43) Pub. Date: Aug. 30, 2007

(54) VERTICAL CAVITY SURFACE EMITTING LASER

(75) Inventors: Yuichiro Hori, Yokohama-shi (JP); Tatsuro Uchida, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/678,471

(22) Filed: Feb. 23, 2007

(30) Foreign Application Priority Data
Feb. 28, 2006 (JP) 2006-053850

(51) Int. Cl. H01S 5/00; H01S 3/08

(52) U.S. Cl. 372/50.124; 372/102

(57) ABSTRACT

In a vertical cavity surface emitting laser including a cavity structure formed by arranging a first reflector (102), an active region (104) and a second reflector (107) on a substrate, the second reflector is formed to include a refractive index periodic structure having a first medium showing a first refractive index and a second medium showing a second refractive index lower than the first refractive index. The first medium and the second medium are arranged periodically in an in-plane direction of the substrate and an electrically conductive adjacent layer made of a material showing a refractive index lower than the first refractive index is arranged at a position adjacent to the second reflector between the active region and the second reflector.

### BACKGROUND OF THE INVENTION

1. Field of the Invention

The present invention relates to a vertical cavity surface emitting laser.

2. Description of the Related Art

Known surface emitting lasers include vertical cavity surface emitting lasers prepared by sandwiching an active region at opposite sides thereof between two reflectors and forming an optical resonator in the direction perpendicular to the substrate surface so as to emit a light beam in the direction perpendicular to the substrate surface.

Research efforts have been intensively paid on vertical cavity surface emitting lasers since the late 1980s because they provide a number of advantages as listed below.

This type of surface emitting laser shows a low threshold and a low power consumption rate and gives rises to a circular spot profile so that the surface emitting laser can be coupled with an optical element with ease and arranged to form an array.

However, since this type of surface emitting laser has a small gain region, the pair of distributed brag reflectors (to be referred as DBRs hereinafter) that produce a cavity are required to show a reflectivity not lower than 99%.

In the case of semiconductor reflectors, they are required to be formed from a multilayer film having tens of layers in order to realize such reflectors. Then, because of this large thickness of the multilayer film, heat can be trapped in the cavity and the cavity tends to show a large threshold and/or a large electric resistance to make a current injection difficult and give rise to other problems.

Proposals have been made to date for cavity reflectors that can replace such DBRs.

For example, V. Lousse et al., Opt. Express, vol. 12, No. 15, p. 3436 (2004) reports the wavelength dependency of reflected light and that of transmitted light when a two-dimensional slab photonic crystal is used as reflector.

A photonic crystal is a structure of a material that is artificially provided with refractive index modulation of about the wavelength of light. In other words, it is a structure where mediums having mutually different respective refractive indexes are disposed periodically. With a photonic crystal, it is believed to be possible to control the propagation of light in crystal due to the multiple scattering effect of light.

According to the above V. Lousse et al article, a hole type two-dimensional photonic crystal is formed as two-dimensional photonic crystal by periodically arranging holes in a slab material having a high refractive index. It is reported that light of a predetermined frequency is reflected with an efficiency of about 100% when such light is made to strike the plane of such a two-dimensional photonic crystal in a direction substantially perpendicular to the plane.

When such a two-dimensional (or one-dimensional) photonic crystal is arranged in a direction perpendicular to the direction of resonance of light as reflector of a vertical cavity surface emitting laser, the reflector can be formed by using a very thin film.

More specifically, a reflector that has conventionally been formed by a multilayer film with a thickness of several micrometers can now be formed by a very thin film having a thickness of tens to hundreds of several nanometers.

Then, as a result, it is possible to significantly alleviate the problems of a thick reflector such as the difficulty of discharging heat and a high electric resistance. Such a thin reflector will be referred to as photonic crystal reflector hereinafter.

H. T. Hattori et al., Opt. Express, vol. 11, No. 15, p. 1808 (2003) discloses an example of numerical computations for the structure of a surface emitting laser where a one-dimensional photonic crystal reflector is used in an actual surface emitting laser device and combined with a DBR to form a cavity. More specifically, the computations are based on an assumption that air layers are arranged on the top and the bottom of a refractive index period structure as shown in FIG. 2 of the accompanying drawings. The region 203 in FIG. 2 lying under the photonic crystal reflector is referred to as air gap layer. In the device of FIG. 2 described in the H. T. Hattori et al article, the layer located adjacent to the photonic crystal reflector is formed by using an air gap structure as a clad section.

In FIG. 2, there are illustrated a DBR 201, an active layer 202, an air gap structure 203 and a photonic crystal reflector 204.

### SUMMARY OF THE INVENTION

However, when a device having a configuration as described above is made to operate by a current injection, it is difficult to inject an electric current into the active region arranged immediately under the reflector because of the air layer immediately under the photonic crystal reflector.

Thus, it is the object of the present invention to provide a laser that uses a photonic crystal reflector in which an electric current can be injected with ease into the active region arranged immediately below the reflector.

According to the present invention, the above object is achieved by providing a vertical cavity surface emitting laser having a configuration as described below.

According to an aspect of the invention, there is provided a vertical cavity surface emitting laser including a cavity formed by arranging a first reflector, an active region and a second reflector on a substrate; the second reflector being formed to include a refractive index periodic structure having a first medium showing a first refractive index and a second medium showing a second refractive index lower than the first refractive index, the first medium and the second medium being arranged periodically in an in-plane direction of the substrate; an electrically conductive adjacent layer made of a material showing a refractive index lower than the first refractive index being arranged at a position adjacent to the second reflector between the active region and the second reflector.

In a vertical cavity surface emitting laser according to another aspect of the invention, the material of the adjacent layer is an electrically conductive material showing a refractive index lower than the first medium of the refractive index periodic structure by more than 10%.

In a vertical cavity surface emitting laser according to still another aspect of the invention, the adjacent layer has such an electric conductivity that an electric current can be injected in the active region immediately below the refractive index periodic structure by way of the adjacent layer.

In a vertical cavity surface emitting laser according to still another aspect of the invention, at least one of the reflectors that define the cavity is formed by laying a plurality of layers each having a periodic structure and an adjacent layer is arranged adjacent to each of the layers of the multilayer periodic structure.

In a vertical cavity surface emitting laser according to still another aspect of the invention, at least one of the reflectors that define the cavity is a distributed Bragg reflector and the other is a one-dimensional or two-dimensional photonic crystal having a periodic structure.

In a vertical cavity surface emitting laser according to still another aspect of the invention, both of the pair of reflectors that define the cavity are one-dimensional or two-dimensional photonic crystals having a periodic structure.

In a vertical cavity surface emitting laser according to still another aspect of the invention, the periodic structure is covered by an electrically conductive medium showing a refractive index lower than the first medium showing the first refractive index of the periodic structure by not less than 10%.

In a vertical cavity surface emitting laser according to still another aspect of the invention, the first medium showing the first refractive index of the periodic structure is a dielectric.

In a vertical cavity surface emitting laser according to still another aspect of the invention, the first medium showing the first refractive index of the periodic structure is a semiconductor.

In a vertical cavity surface emitting laser according to still another aspect of the invention, a site that disturbs the periodicity of the periodic structure is arranged in the latter.

In a vertical cavity surface emitting laser according to still another aspect of the invention, the adjacent layer functions as current injection channel at the same time as confining light in the periodic structure.

Thus, according to the present invention, it is possible to realize a laser that uses a photonic crystal reflector in which an electric current can be injected with ease into the active region arranged immediately below the reflector.

Further features of the present invention will become apparent from the following description of the exemplary embodiments with reference to the attached drawings.

### BRIEF DESCRIPTION OF THE DRAWINGS

FIG. 1 is a schematic cross-sectional view of an embodiment of vertical cavity surface emitting laser according to the present invention, illustrating the basic configuration thereof.

FIG. 2 is a schematic cross-sectional view of a vertical cavity surface emitting laser of a prior art, illustrating the basic configuration thereof.

FIG. 3 is a schematic perspective view of a two-dimensional photonic crystal that can be used for an embodiment of the present invention.

FIG. 4 is a schematic perspective view of a two-dimensional photonic crystal that can be used for an embodiment of the present invention, illustrating how light is reflected by the crystal or transmits through the crystal.

FIGS. 5A and 5B schematically illustrate the vertical cavity surface emitting laser of Example 1 of the present invention, FIG. 5A is a schematic cross-sectional view of the vertical cavity surface emitting laser of Example 1 taken along a direction perpendicular to the substrate thereof and FIG. 5B is a schematic plan view of the upper cavity reflector of the vertical cavity surface emitting laser of Example 1 as viewed in a direction perpendicular to the reflector plane.

FIGS. 6A and 6B schematically illustrate the vertical cavity surface emitting laser of Example 2 of the present invention, FIG. 6A is a schematic cross-sectional view of the vertical cavity surface emitting laser of Example 2 taken along a direction perpendicular to the substrate thereof and FIG. 6B is a schematic plan view of the upper cavity reflector of the vertical cavity surface emitting laser of Example 2 as viewed in a direction perpendicular to the reflector plane.

FIG. 7 is a schematic cross-sectional view of the vertical cavity surface emitting laser of Example 3 of the present invention taken along a direction perpendicular to the substrate thereof.

FIG. 8 is a schematic cross-sectional view of the vertical cavity surface emitting laser of Example 4 of the present invention taken along a direction perpendicular to the substrate thereof.

FIGS. 9A and 9B schematically illustrate the vertical cavity surface emitting laser of Example 5 of the present invention, FIG. 9A is a schematic cross-sectional view of the vertical cavity surface emitting laser of Example 5 taken along a direction perpendicular to the substrate thereof and FIG. 9B is a schematic plan view of the upper cavity reflector of the vertical cavity surface emitting laser of Example 5 as viewed in a direction perpendicular to the reflector plane.

FIG. 10 is a schematic cross-sectional view of the vertical cavity surface emitting laser of Example 6 of the present invention taken along a direction perpendicular to the substrate thereof.

### DESCRIPTION OF THE EMBODIMENTS

Now, the present invention will be described in greater detail by referring to the accompanying drawings that illustrate a preferred embodiment of the invention.

Firstly, the basic structure of the embodiment of vertical cavity surface emitting laser according to the present invention will be described.

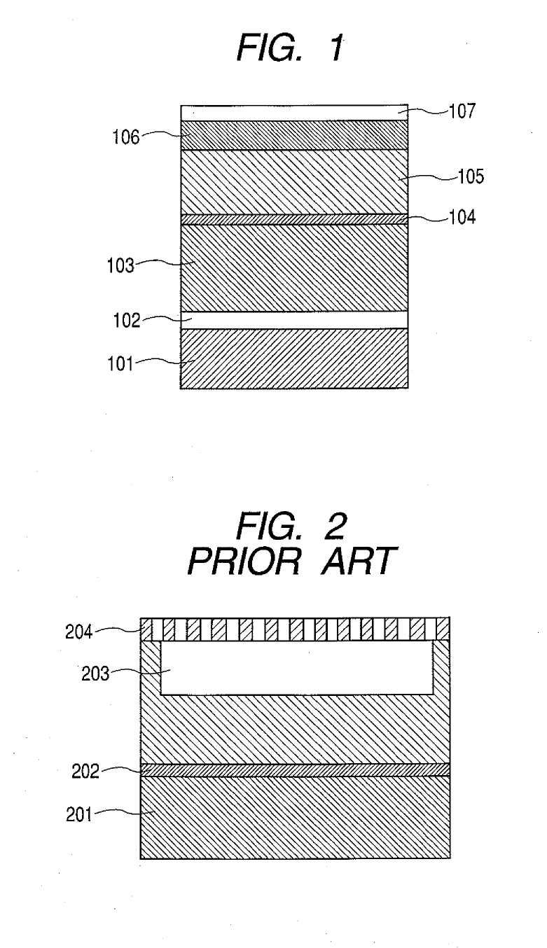

FIG. 1 is a schematic cross-sectional view of the embodiment of vertical cavity surface emitting laser according to the present invention, illustrating the basic configuration thereof. In FIG. 1, there are illustrated a substrate 101, a lower reflector layer (first reflector) 102 and an upper reflector layer (second reflector) 107. In FIG. 1, clad layers 103 and 105 sandwich an active layer between them, and there are also illustrated an active layer 104 and a cavity reflector adjacent clad layer (adjacent layer) 106. Additionally, the vertical cavity surface emitting laser is provided with electrodes (not shown) for current injection. The second reflector 107 has a refractive index periodic structure formed by periodically arranging a first medium showing a first refractive index and a second medium showing a second refractive index lower than the first refractive index in an in-plane direction of the substrate. Between the active layer 104 and the second reflector 107, the layer 106 made of an electrically conductive material that shows a refractive index lower than the first refractive index is arranged at a position adjacent to the second reflector.

As an electrically conductive material is placed immediately below the refractive index periodic structure, it is easy to inject an electric current into the active layer arranged immediately below and effectively confine light to the reflectors as such confinement is required when a photonic crystal is used as a reflector in the vertical direction.

A photonic crystal that is a subject of intensive research efforts in recent years can be used for the refractive index periodic structure of the vertical cavity surface emitting laser of this embodiment.

Before getting into the embodiment of the present invention, photonic crystals will firstly be described.

Photonic crystals can be classified into one-dimensional crystals through three-dimensional crystals from the viewpoint of the number of direction in which the refractive index period is disposed.

Among photonic crystals, one-dimensional and two-dimensional photonic crystals where the refractive index periodically changes in in-plane directions have hitherto been objects of technological researches because such crystals can be prepared relatively easily.

For examples, of two-dimensional photonic crystals, those having a refractive index periodic structure formed from a thin plate-shaped material to show periodicity in in-plane directions are specifically referred to as two-dimensional slab photonic crystals.

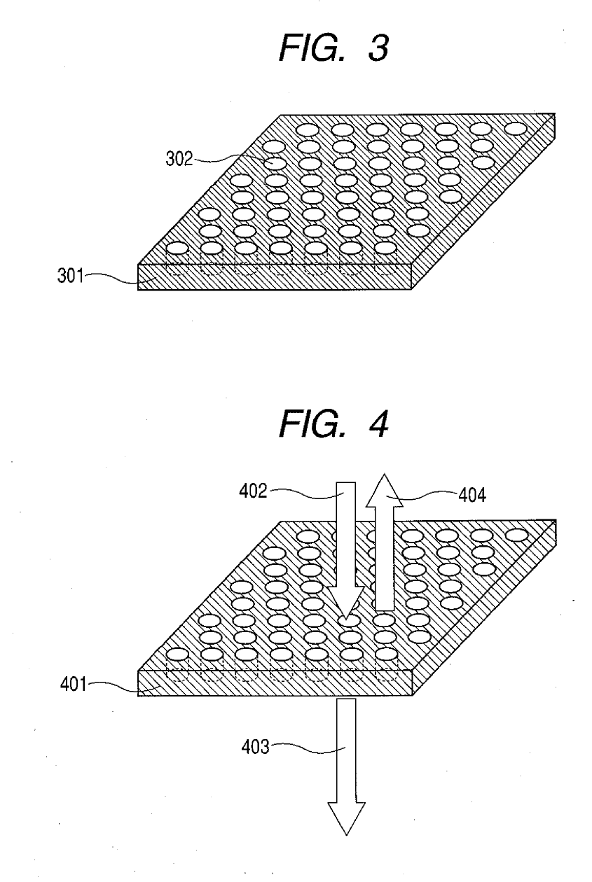

For instance, it is possible to modulate the refractive index of a two-dimensional slab photonic crystal in in-plane directions by boring micro holes 302 through a thin plate 301 of a semiconductor showing a high refractive index such as Si at a period substantially equal to the wavelength of light to be used as shown in FIG. 3.

Thus, it is possible to control the propagation of light in crystal in the directions in which the refractive index period is provided by using photonic crystal.

Therefore, as for two-dimensional photonic crystals, the photonic crystal acts on light mainly in the in-plane directions in which the refractive index periodic structure is provided.

More specifically, it is possible to control light in various different ways. For instance, it is possible to confine light to a micro region, reduce the group velocity of light and change the direction of propagation of light.

As a characteristic of photonic crystal, it is known that light within a certain frequency band cannot exist in the inside of photonic crystal (and this frequency band is referred to as photonic band gap).

As portions where the periodicity is disturbed (defect portions) are introduced into photonic crystal, the characteristic of photonic band gap is lost in the defect portions. Then, light within the frequency band can exist there.

Thus, it is possible to confine light to a micro region by providing a photonic crystal with defect portions as a part thereof and surrounding them with photonic crystal.

It is also known that two-dimensional photonic crystal shows particular properties relative to light having a wavenumber component in a direction perpendicular to the crystal plane.

The property of photonic crystal of reflecting incident light by 100% as described in the above-mentioned V. Lousse et al article is an example of such properties.

These properties of photonic crystal are mainly used for the purpose of the present invention.

Now, the refractive index periodic structure of photonic crystal will be described further below.

As pointed out above, a photonic crystal can be used for the refractive index periodic structure of a cavity reflector of the vertical cavity surface emitting laser of this embodiment.

The underlying principle will be described below by referring to an example where a two-dimensional slab photonic crystal is used for a reflector, which is particularly important for the purpose of the present invention. Firstly, a photonic crystal reflector will be summarily described.

FIG. 4 is a schematic perspective view of a two-dimensional photonic crystal, illustrating how light strikes the crystal. As light is made to strike the two-dimensional photonic crystal 401 in a direction substantially perpendicular to the crystal plane (in FIG. 4, incident light 402, transmitted light 403 and reflected light 404 are illustrated), the transmission spectrum of the light shows a complex profile.

For instance, the V. Lousse et al article proves by simulation that the reflectivity is 99% or more in three wavelength regions of 1,100 nm, 1,220 to 1,250 nm and around 1,350 nm.

A transmission spectrum in an infrared region obtained by an experiment is also shown.

Thus, a photonic crystal can be used as reflector by utilizing the above described properties for reflection.

The above-described phenomenon occurs because light 402 entering in a direction substantially perpendicular to the two-dimensional photonic crystal is transformed to light that is propagating in the in-plane directions of the photonic crystal once and resonates in the in-plane directions before the light exits in the perpendicular direction at the side of incident light.

The above-described properties are observed not only in two-dimensional photonic crystals but also in one-dimensional photonic crystals.

Two-dimensional photonic crystals are generally formed by periodically arranging a low refractive index medium in a high refractive index medium.

Instances where a low refractive index medium is arranged to form a triangular lattice, a rectangular lattice or a circular coordinate system have been reported.

It is possible to control the reflection characteristic of a reflector by changing the periodicity and/or the volume of the low refractive index medium.

It may be needless to say that the low refractive index medium and the high refractive index medium can be interchanged in the above description.

The reflection characteristic of a reflector can be controlled also by adjusting the thickness of a refractive index periodic structure of photonic crystal as viewed in a direction perpendicular to the structure (to the crystal plane).

Additionally, the thickness in the direction perpendicular to the plane of the two-dimensional photonic crystal is preferably smaller than a predetermined value so that the crystal may not show a multi-mode where the transverse mode is predominant for light propagating through the crystal in two-dimensional in-plane directions.

While the above-cited predetermined value may vary depending on the wavelength of propagating light and the material of the photonic crystal, it is possible to lead out the predetermined value by means of a known theoretical calculation (for example, K. Okamoto, “Fundamentals of Optical Waveguides”, Chapter 2, Optronics).

Now, the refractive index periodic structure and the layer adjacent to the refractive index periodic structure will be described below.

In the vertical cavity surface emitting laser of this embodiment, the layer adjacent to the refractive index periodic structure of the reflector is desirably made of an electrically conductive medium showing a refractive index lower than the first medium of the refractive index periodic structure that shows the first refractive index by not less than 10%.

With this arrangement, it is possible to inject an electric current in a direction substantially perpendicular to the light emitting region of the active layer while keeping the refractive index of the medium adjacent to the photonic crystal reflector sufficiently lower than the reflector.

As pointed out above, resonance takes place in in-plane directions of the photonic crystal reflector in a propagation mode where light is guided two-dimensionally in the photonic crystal.

According to the general principle of waveguide, in such a propagation mode, light is apt to be confined to a waveguide where the refractive index of the adjacent layer is lower than that of the material of the photonic crystal particularly by a large difference (Δ).

Then, as a result, reflection by the refractive index periodic structure is also apt to take place and shows a good performance when Δ is large. It is also possible to prepare a device that can resist degradation of performance of the reflector if a manufacturing error is involved.

Due to the above-described principle, while it is generally better for A to be large to achieve a high reflectivity, the behavior of reflectivity is rather complex relative to Δ (in other words, the reflectivity is not so simple as to be proportional to Δ).

However, the reflectivity falls when Δ is very small relative to the refractive index of the medium of the photonic crystal reflector.

More specifically, a reported simulation shows that the reflectivity falls significantly when Δ is not larger than 10% of the refractive index of the medium of the photonic crystal reflector (OPTICS EXPRESS, Vol. 13, No. 17, p. 6564).

Therefore, to realize a reflector showing a high reflectivity, it is desirable that Δ is not less than 10% of the refractive index of the medium of the photonic crystal reflector.

Then, it is possible to inject an electric current substantially perpendicularly into the light emitting section of the active layer by placing the electrically conductive medium meeting the requirement adjacent to the photonic crystal (the layer 106 in FIG. 1). Then, it is possible to provide a surface emitting laser device into which an electric current can be injected efficiently while maintaining the good performance of the reflector.

When a semiconductor is used for forming the vertical cavity surface emitting laser of this embodiment, the material of the clad layer is generally a high refractive index medium.

If such is the case, it is preferable that the electrically conductive low refractive index medium is placed adjacent to the photonic crystal reflector at the side of the active layer for the purpose of improving the performance of the photonic crystal reflector.

This arrangement is adopted for the embodiment of FIG. 1.

It is also possible to place the electrically conductive low refractive index medium adjacent to the photonic crystal reflector both at the side of the active layer and at the side opposite to the active layer.

Alternatively, the electrically conductive low refractive index medium may be used for the low refractive index medium of the photonic crystal.

If such is the case, it is also preferable to place the electrically conductive low refractive index medium adjacent to the photonic crystal reflector at the side of the active layer.

Now, the materials of the vertical cavity surface emitting laser of this embodiment will be described below.

The materials will be described from the viewpoint of each component.

Firstly, various semiconductors and dielectrics may be used for the materials of the inside of the cavity (the clad layer+the active layer).

Semiconductors that can be used as such materials include Group III-V semiconductors such as GaAs, AlGaAs, AlInGaP, GaInAsP, GaInNAs, GaN, AlN and InN and mixed crystals of any of them as well as group II-VI semiconductors such as ZnSe, CdS and ZnO and mixed crystals of any of them.

Dielectrics that can be used as such materials include solid laser mediums such as Ti:Sapphire and YAG (yittrium garnet).

Any of the above-listed mediums may be used in combination for the clad layer and the active layer. Note, however, that it is preferable to use semiconductors for the internal structures of the cavity to make the surface emitting laser operate more actively by injecting an electric current.

The medium of the photonic crystal reflector can be selected from semiconductors, dielectrics and metals.

Semiconductors that can be used for the medium of the photonic crystal reflector include the above listed materials of Group III-V type and of Group II-VI type.

Dielectrics that can be used for the medium of the photonic crystal reflector include a number of materials such as TiO₂, Al₂O₃, Nb₂O₅, CeO₂, ZrO₂ and HfO₂.

Metals that can be used for the medium of the photonic crystal reflector include any solid metal crystals such as Au, Ag, Cr and Co.

The material of the photonic crystal reflector is preferably a medium that absorbs little light of the oscillation wavelength.

Therefore, the use of a transparent semiconductor or dielectric is preferable relative to oscillated light.

Additionally, when a dielectric is used, a high refractive index material such as TiO₂, Nb₂O₅ or ZrO₂ is preferable from the viewpoint of confining light to the reflector.

The layer arranged adjacent to the photonic crystal needs to be made of a material that shows a low refractive index to a certain extent and is electrically conductive.

Examples of materials that can be used for the layer include transparent electrically conductive oxides such as ITO (indium tin oxide), SnO₂, In₂O₃ and ZnO and organic semiconductors. The substrate to be used for the device may be made of a material selected from semiconductors, dielectrics and metals. However, it is preferably made of a material selected from semiconductors and metals from the viewpoint of injecting an electric current.

Any electrodes that can be used for ordinary semiconductor processes and transparent electrodes may be used for the electrodes of the vertical cavity surface emitting laser of this embodiment. While materials that can be used for different components of the vertical cavity surface emitting laser of this embodiment are described above, any combinations of any of the above listed materials can be used for the respective components of the vertical cavity surface emitting laser of this embodiment.

Now, techniques that can be used for injecting an electric current will be described below.

Any techniques that employ a unit having a pair of electrodes including an anode and a cathode to inject carriers into the active layer 104 by injecting an electric current from the electrodes may be used for this embodiment.

The electrodes may be arranged on the cavity reflector or on the cavity reflector adjacent clad layer 106.

When the cavity reflector is made of a semiconductor or metal, the electrodes may be arranged on the cavity reflector or on the low refractive index electrically conductive layer.

However, if the refractive index periodic structure is formed by a solid medium and holes, it is preferable that the periodic structure pattern is not formed in regions immediately under the electrodes.

This is because the contact resistance can vary significantly when holes are present.

When the cavity reflector is made of a dielectric, it is arranged on the low refractive index electrically conductive layer. When the cavity reflector is arranged on the low refractive index electrically conductive layer, it is preferable to implement an aperture layer, which is an insulating layer, immediately under the electrically conductive layer so that an electric current may be injected into the light emitting region of the active layer effectively.

The electrodes may be selected from ring-shaped electrodes that are used in ordinary vertical cavity surface emitting lasers and electrodes having other various profiles such as circular and rectangular.

As for the material of the electrodes, any electrode materials that have conventionally been used with semiconductor laser technologies may also be used for the purpose of the present invention.

For example, materials such as Au—Ge—Ni or Au—Sn may be used for n-type GaAs, while Au—Zn or In—Zn may be used for p-type GaAs.

Since the above described low refractive index transparent electrically conductive layer can also be used as electrode material, the electrically conductive layer may also be made to operate as electrode.

Now, the types of the reflectors of the cavity will be described below.

The reflectors of the cavity of the vertical cavity surface emitting laser of this embodiment can be selected from photonic crystal reflectors and DBRs.

For example, two photonic crystal reflectors may be used for the two cavity reflectors or a photonic crystal reflector and a DBR may be used in combination for the two cavity reflectors of this embodiment.

When a photonic crystal reflector is used, it is necessarily to be accompanied by an adjacent low refractive index layer.

Combinations of materials that can be used for a DBR for the purpose of the present invention include the following.

Namely, they include combinations of semiconductors having lattice constants that are relatively close to each other such as InₓGa₁₋ₓAs_{y}P_{1-y}/Inₓ′Ga₁₋ₓ′As_{y}P_{1-y}′, AlₓGa₁₋ₓAs/Al_{y}Ga_{1-y}As and GaN/AlₓGa₁₋ₓN and any combinations of dielectrics such as TiO₂, SiO₂, HfO₂, ZrO₂, Al₂O₃, Nb₂O₅ and CeO₂.

Now, an arrangement where one or more than one defects are introduced into the refractive index periodic structure will be described below.

In the vertical cavity surface emitting laser of this embodiment, it is possible to introduce a structure that disturbs the refractive index periodic structure of the cavity reflector, or a so-called defective structure.

Any defect that disturbs or defects that disturb the refractive index periodic structure may be used.

In the case of a structure where a low refractive index medium and a high refractive index medium are arranged periodically, a region of the low refractive index medium may be replaced with a region of the high refractive index medium or the volume of a region of the low refractive index medium may be differentiated from that of the other regions to produce a defect.

It is also possible to arrange a plurality of such defects to produce a linear defect or a surface defect.

Such defects may be arranged periodically to produce periodic defects or non-periodically to produce non-periodic defects.

As non-periodic defects, defects may be arranged at random or alternatively the period of defects may be varied according to a certain law. Still alternatively, the period of defects may be made anisotropic.

A photonic crystal reflector having one or more than one defects can change the transverse mode of reflected light and transmitted light, the near- and far-field images and/or the oscillation band due to the defect or defects.

As for reflection of light by a photonic crystal reflector having defects, incident light whose mode is converted into a guided mode may be localized in each defect and guided (to be referred to as defect mode hereinafter) or may not be localized.

When light is reflected by a photonic crystal reflector having defects, light localized in each defect can be coupled one after another with localized lights in adjacent defects to spread over the entire surface. In such a case, reflected light can be controlled remarkably by changing the arrangement of the defects.

However, the following two requirements have to be satisfied. One of the requirements is that the photonic crystal needs to have a photonic band gap relative to reflected light.

The other is that the defects are arranged adjacently within a predetermined range of distances so that localized lights may be coupled with each other.

The required distance separating adjacent defects can vary depending on the wavelength of reflected light, the lattice parameter of the photonic crystal and other factors.

Now, an arrangement where a reflector is formed by a multilayer film having a plurality of refractive index periodic structures will be described below.

A refractive index periodic structure to be used for the pair of reflectors of the cavity of the vertical cavity surface emitting laser of this embodiment may be used alone or a plurality of such structures may be combined for the use.

For example, when the refractive index periodic structure is formed from two-dimensional photonic crystal, a plurality of two-dimensional photonic crystals may be laid one on the other in the vertical direction of the reflector planes to form at least one of the cavity reflectors.

Such two-dimensional photonic crystals may be replaced by one-dimensional photonic crystals or three-dimensional photonic crystals.

A multilayer film reflector may be formed by arranging a spacer layer of air or some other medium between a refractive index periodic structure region showing a certain periodicity and a refractive index period structure region showing another periodicity so that a period may be provided by a pair of a refractive index periodic structure and a spacer layer for the cavity reflector.

Preferably, such pairs are designed to establish phase matching of light that resonates in the reflector. The following two requirements have to be met for phase matching.

One of the requirements is that the positional relationship in in-plane directions of the two-dimensional photonic crystal is always constant and the other is that the thickness of the pair of two layers is adjusted under the condition that the first requirement is satisfied. As for the first requirement, a problem may arise when the spacer layer is thin between refractive index periodic structure layers and two or more than two refractive index periodic structures are optically coupled.

In such a situation, the refractive index periodic structures need to be aligned (by translation and/or rotation) with each other in in-plane directions. If they are not aligned with each other, the reflectivity and the reflection wavelength of the reflector and the phase of light irradiated in the vertical direction from the refractive index periodic structure vary from layer to layer to consequently reduce the reflectivity.

The positional relationship is preferably constant even when the spacer layer is thick and refractive index periodic structures are not optically coupled.

For example, when a number of two-dimensional photonic crystals showing the same periodicity are laid one on the other, the positional relationship may be such that the positions of the holes thereof agree with each other with an accuracy level of not allowing any error greater than 10 nm.

The second requirement is satisfied by adjusting the thickness of two layers under the condition that the first requirement is met. However, it is not preferable to increase the thickness of the refractive index periodic structure layer because the mode in the longitudinal direction becomes a multimode when the thickness is too large.

In other words, it is desirable to adjust the thickness of two layers by fixing the thickness of the refractive index periodic structure layer and changing the thickness of the spacer layer.

Materials that can be used for the spacer layer include metals, semiconductors, dielectrics and air. When an electric current is injected by way of the reflector, it is preferable that the spacer layer is made of a metal or a semiconductor.

However, in view of the fact that metal absorbs light, the spacer layer is preferably made of a semiconductor that is transparent to the oscillation wavelength in order to reduce the threshold of the laser.

Additionally, it is necessary to make adjacent layers show a difference between their refractive indexes in order not to degrade the performance of the photonic crystal reflector as pointed out above.

Thus, the refractive index of the spacer layer is preferably lower than that of the medium of the photonic crystal reflector by not less than 10%.

Particularly, it is useful to use a transparent and electrically conductive medium for the spacer layer to satisfy both the above requirements and the requirement of electric conductivity.

Now, the present invention will be described further by way of examples.

The examples shown below are exemplary and the material, the size, the profile and other factors of the laser device to be used for the purpose of the present invention are by no means limited by Examples 1 through 6 that are described below.

### EXAMPLE 1

The vertical cavity surface emitting laser according to the present invention of Example 1 will be described below.

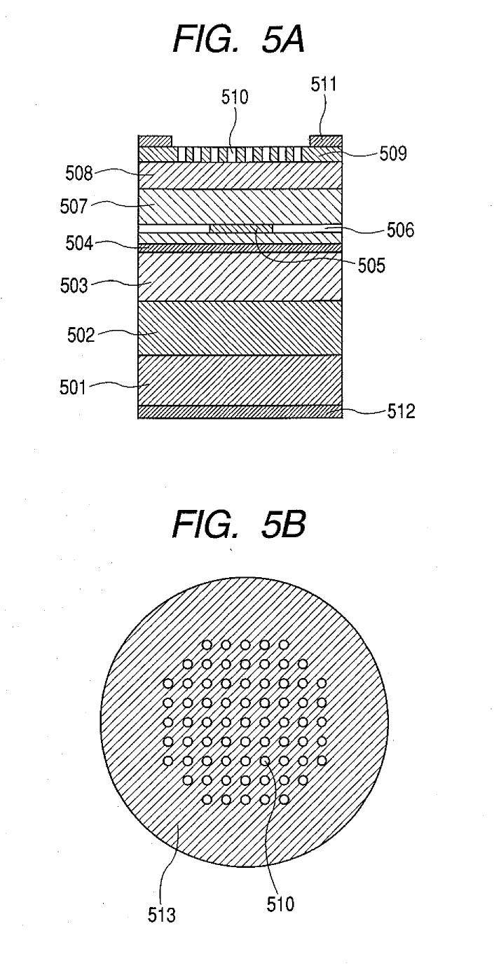

FIGS. 5A and 5B schematically illustrate the vertical cavity surface emitting laser of Example 1 of the present invention. FIG. 5A is a schematic cross-sectional view of the vertical cavity surface emitting laser of Example 1 taken along a direction perpendicular to the substrate thereof and FIG. 5B is a schematic plan view of the upper cavity reflector of the vertical cavity surface emitting laser of Example 1 as viewed in a direction perpendicular to the reflector plane.

In FIGS. 5A and 5B, there are illustrated a substrate 501, a lower cavity reflector layer 502, a lower clad layer 503, an active layer 504, an oxide aperture layer center portion 505 and an oxide aperture layer 506.

Additionally, there are also illustrated an upper clad layer 507, an upper cavity reflector adjacent clad layer 508, an upper cavity reflector layer 509, upper cavity reflector holes 510, a p-electrode 511 and an n-electrode 512.

Now, the materials, the dimensions and the functions of the component sections of the vertical cavity surface emitting laser of this example will be described below.

The substrate 501 is GaAs and has a thickness of 550 μm.

The lower cavity reflector layer 502 is a DBR of n-type Al_{0.5}Ga_{0.5}As/Al_{0.93}Ga_{0.07}As and the number of pairs of the component layers is 70 pairs.

The thickness of each of the layers is λ/4 of the oscillation wavelength as reduced to the optical path length. In this example, the oscillation wavelength is 670 nm, which is that of red light and hence the layers of each pair have respective thicknesses of 48 nm and 53 nm. The materials of the layers are arranged in the above listed order as viewed from the clad layer of the cavity to form a multilayer structure.

Now, the upper cavity reflector will be described by referring to FIG. 5B.

In FIG. 5B, there is illustrated an electrode forming region 513.

The upper cavity reflector layer 509 is a photonic crystal reflector prepared by periodically boring holes 510 through a 150 nm-thick semiconductor slab.

The photonic crystal region is formed to show a circular profile with a diameter of 20 μmφ.

Although not clearly shown in FIG. 5B, the photonic crystal structure is formed with 80 periods.

In this example, the region 513 surrounding the photonic crystal is the region for forming an electrode and hence no photonic crystal pattern is arranged in this region. The diameter of the mesa portion including the photonic crystal region and the surrounding region is 40 μmφ. The holes of the photonic crystal are circular and a column structure is formed by extending the circle in the perpendicular direction of the photonic crystal reflector surface.

The holes are arranged to form a rectangular lattice in-plane directions of the reflector.

The reflectivity is designed to be maximized at and near 670 nm that is the oscillation wavelength. The parameters of the photonic crystal of this example include a hole period of 250 nm and a hole diameter of 150 nm. The material of the upper cavity reflector layer is Al_{0.5}Ga_{0.5}As.

The lower clad layer 503 and the upper clad layer 507 are respectively made of n-type and p-type AlGaInP and have respective thicknesses of 635 nm and 475 nm. The upper clad layer is bounded by the oxide aperture layer center portion 505 and the oxide aperture layer 506 and the thickness includes that of the center portion 505 and the layer 506. The active layer 504 has a multiple quantum well structure of Ga_{0.56}In_{0.44}P/(Al_{0.5}Ga_{0.5})_{0.5}In_{0.5}P.

The number of wells is three and the thickness of the Ga_{0.56}In_{0.44}P well layer and that of the (Al_{0.5}Ga_{0.5})_{0.5}In_{0.5}P layer between two well layers are equally 6 nm.

The oxide aperture layer center portion 505 is AlAs and the oxide aperture layer 506 is Al₂O₃. Both of them have a constant thickness of 20 nm.

The oxide aperture layer center portion 505 is made to show a diameter so as to allow the device to oscillate in a single mode. In this example, the diameter is 3 μmφ.

The upper cavity reflector adjacent clad layer 508 is made of ITO and has a thickness of 300 nm.

ITO shows a refractive index of about 1.9 (670 nm), which is low relative to that of Al_{0.5}Ga_{0.5}As (refractive index: 3.49) of the upper cavity reflector, the difference being about 45% relative to Al_{0.5}Ga_{0.5}As.

Therefore, as pointed out above, the provision of this layer makes it easier to confine light in the inside of the photonic crystal reflector, which is the upper cavity reflector, to consequently improve the performance of the photonic crystal reflector.

Additionally, since ITO shows a level of electric conductivity of about 1×10⁻⁴ Ω·cm as expressed by resistivity, this layer can be used as an electric current injection channel.

Thus, it is possible to facilitate the injection of an electric current in the direction perpendicular to the active layer to improve the injection efficiency, while maintaining the performance of the photonic crystal reflector, which is the upper cavity reflector.

The sections of the cavity except the reflectors are formed as a result of combining the lower clad layer, the upper clad layer, the active layer, the oxide aperture layer, the oxide aperture layer center portion and the upper cavity reflector adjacent clad layer. The cavity length is 6.5 wavelengths.

The p-electrode is a ring-shaped electrode formed around the region of the upper cavity reflector where the photonic crystal structure is found. The material thereof is Au—Ge—Ni. The n-electrode is made of Au—Zn and formed on the entire area of the rear side.

Now, the method of manufacturing the vertical cavity surface emitting laser of this example will be described below.

The vertical cavity surface emitting laser of this example is prepared based on an ordinary semiconductor process that can be used when preparing conventional vertical cavity surface emitting lasers. It can be prepared by adding a bonding step and other steps to the semiconductor process.

Firstly, the multilayer film structure up to the upper clad layer is formed on an n-type GaAs substrate by crystal growth.

Then, an ITO film is formed by sputtering on the upper clad layer as the upper cavity reflector adjacent clad layer.

Thereafter, the current confining structure of an AlAs layer is formed by steam oxidation.

Separately, a p-type Al_{0.5}Ga_{0.5}As photonic crystal reflector layer is formed on another GaAs substrate and the hole periodic structure of the photonic crystal reflector layer is formed by EB lithography and dry etching, using Cl₂ gas.

Then, the photonic crystal reflector layer is bonded by hot bonding onto the ITO upper cavity reflector adjacent clad layer prepared formerly. The GaAs substrate that is held in contact with the bonded p-type Al_{0.5}Ga_{0.5}As photonic crystal reflector layer is scraped to reduce the thickness thereof down to immediately above the reflector layer by mechanical polishing and subsequently smoothed by CMP (chemical mechanical polishing). The remaining thin substrate layer is removed by dry etching, using Cl₂ gas.

Finally, the p-electrode Au—Ge—Ni and the n-electrode Au—Zn are formed respectively by evaporation and sputtering, respectively.

While ITO is used for the upper cavity reflector adjacent clad layer in this example, it may alternatively be formed by a transparent electrically conductive film of such as SnO₂ or ZnO as listed earlier for the above described embodiment.

It is possible to use a semiconductor selected from the semiconductors listed earlier for the above described embodiment for the semiconductor portion of the device.

Furthermore, while an aperture structure formed by introducing an oxide layer is used for the current confining layer of this example, it is possible to raise the resistance by injecting protons or replace the structure with an aperture structure of a buried heterostructure. While the photonic crystal reflector of this example has a photonic crystal structure of two-dimensional rectangular lattice, a triangular lattice structure or a circular coordinate system lattice structure may alternatively be used.

It is also possible to use a one-dimensional grating structure in place of the two-dimensional structure.

As the laser device of this example is electrically energized, the device oscillates with a wavelength of 670 nm for red light. Both the reflector performance and the current injection efficiency can be raised and a stable operation of laser oscillation can be realized due to the provision of the upper cavity reflector adjacent clad layer that shows a low refractive index and a good electric conductivity.

### EXAMPLE 2

The vertical cavity surface emitting laser according to the present invention of Example 2 will be described below.

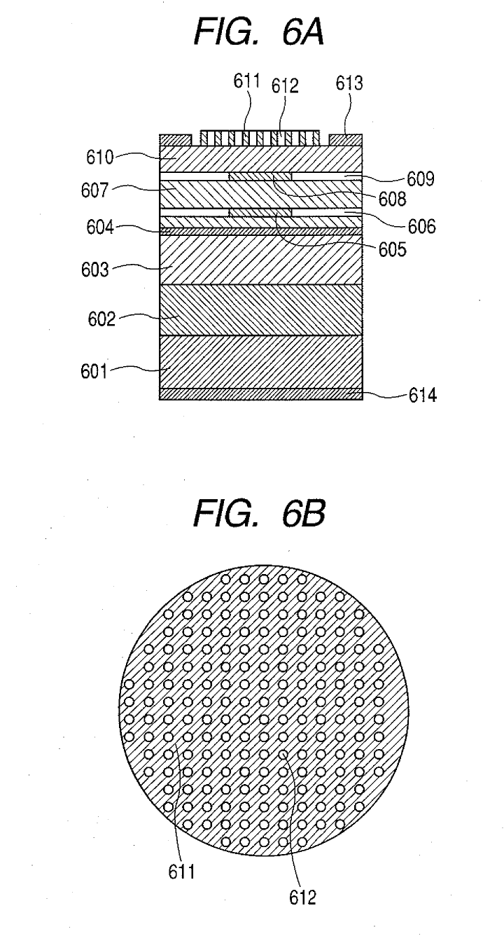

FIGS. 6A and 6B schematically illustrate the vertical cavity surface emitting laser of Example 2 of the present invention. FIG. 6A is a schematic cross-sectional view of the vertical cavity surface emitting laser of Example 2 taken along a direction perpendicular to the substrate thereof and FIG. 6B is a schematic plan view of the upper cavity reflector of the vertical cavity surface emitting laser of Example 2 as viewed in a direction perpendicular to the reflector plane.

In FIGS. 6A and 6B, there are illustrated a substrate 601, a lower cavity reflector layer 602, a lower clad layer 603, an active layer 604, a first oxide aperture layer center portion 605 and a first oxide aperture layer 606.

Additionally, there are also illustrated an upper clad layer 607, a second oxide aperture layer center portion 608, a second oxide aperture layer 609, an upper cavity reflector adjacent clad layer 610, an upper cavity reflector layer 611, upper cavity reflector holes 612, a p-electrode 613 and an n-electrode 614.

The device of this example is identical with Example 1 from the substrate 601 up to the first oxide aperture layer center portion 605 and the first oxide aperture layer 606 along with the n-electrode 614. The specific materials, the dimensions and the functions of these components of the device are the same as those of the device of Example 1.

Therefore, only the differences between this example and Example 1 will be described below.

In this example, a second oxide aperture layer 609 is arranged for confining the electric current at the boundary area of the upper clad layer 607 and the upper cavity reflector adjacent clad layer 610.

The materials and the dimensions of the second oxide aperture layer center portion 608 and the second oxide aperture layer 609 are the same as those of the first oxide aperture layer center portion 605 and the first oxide aperture layer 606.

The upper clad layer is made to 485 nm thick, which is 10 nm longer than that of the counterpart of Example 1 because the second oxide aperture layer center portion 608 and the second oxide aperture layer 609 are added thereto.

Now, the upper cavity reflector will be described below.

In the example, the upper cavity reflector is a photonic crystal reflector as in Example 1. The photonic crystal is formed by periodically arranging holes in the plane layer of TiO₂ and the region where holes are arranged has a diameter of 20 μmφ as in Example 1 but holes are arranged over the entire region of the reflector layer and no space is provided for an electrode to be disposed on the reflector.

While the photonic crystal is formed with a little more than ten periods in FIG. 6B, a photonic crystal structure is formed actually with about 80 periods.

As in Example 1, the holes of the photonic crystal are circular and a column structure is formed by extending the circle in the perpendicular direction to the photonic crystal reflector surface. The holes are arranged to form a rectangular lattice. In this example, the photonic crystal layer has a thickness of 250 nm, a lattice constant of 170 nm and a hole diameter of 50 nm.

The upper cavity reflector adjacent clad layer is made of a transparent electrically conductive ITO film also in this example. The layer has a thickness of 300 nm.

In this case again, the difference of refractive index satisfies the requirement of not less than 10% relative to the photonic crystal reflector so that the upper cavity reflector adjacent clad layer operates as light confining layer for the photonic crystal.

The upper cavity reflector is made of a dielectric in this example. Therefore, an electric current is injected by way of the upper cavity reflector adjacent clad layer.

Thus, the part on the upper cavity reflector adjacent clad layer practically operates as p-electrode and a secondary electrode of Ag is formed thereon.

When an electric current is injected, the current is supplied in an inclined direction to reduce the excitation efficiency of the active layer. Therefore, it is desirable to arrange a second aperture layer immediately under the upper cavity reflector adjacent clad layer so that an electric current can be injected into the light emitting region of the active layer substantially perpendicularly.

In this example, the current confining structure is realized by the oxide aperture layers.

As for the method of manufacturing the laser device of this example, the steps down to forming the upper clad layer are the same as their counterparts of Example 1 because the materials and the structures are the same as or similar to those of Example 1.

Then, an AlAs layer is formed thereon and the ITO upper cavity reflector adjacent clad layer is formed further thereon by sputtering.

Then, the TiO₂ upper cavity reflector layer is formed further thereon also by sputtering. Subsequently, the current confining structure of the AlAs layer is produced by steam oxidation. Then, the hole periodic structure is formed in the photonic crystal reflector layer by EB lithography and dry etching using Cl₂ on the photonic crystal reflector.

Finally, the p-electrode and the n-electrode are formed respectively by evaporation and sputtering.

The laser device of this example can be prepared only by way of film forming steps without using any hot bonding step.

The semiconductors of the laser device of this example can be replaced by any of those listed for the above described embodiment. The photonic crystal reflector can be formed by using a dielectric that shows a relatively high refractive index. Thus, TiO₂ can be replaced by a dielectric of the type described for the embodiment that shows a high refractive index.

Furthermore, while an aperture structure formed by introducing an oxide layer is used for the current confining layer of this example, it is possible to raise the resistance by injecting protons or replace the structure with an aperture structure of a buried heterostructure.

### EXAMPLE 3

The vertical cavity surface emitting laser according to the present invention of Example 3 will be described below.

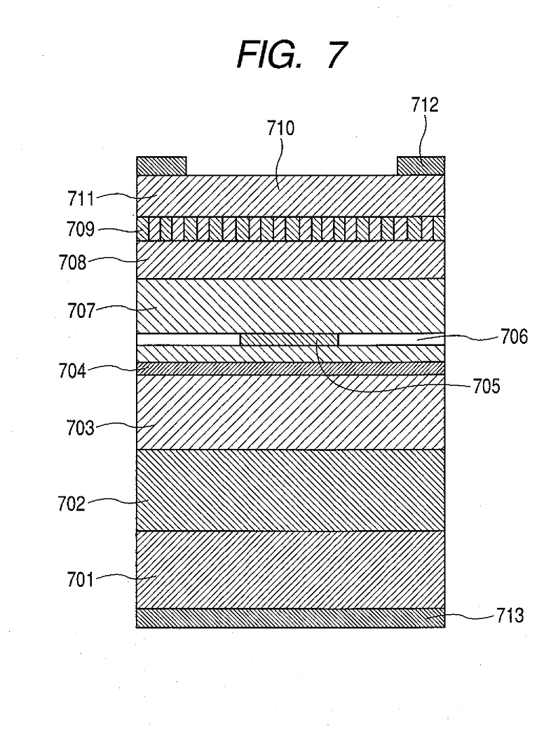

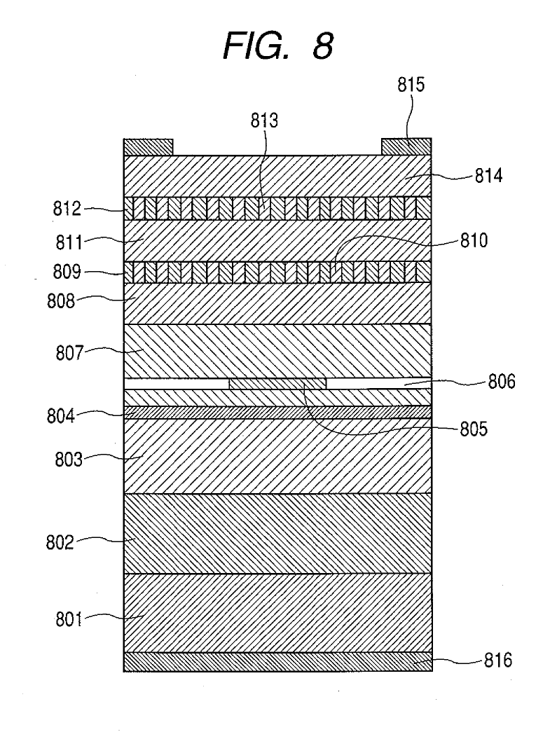

FIG. 7 is a schematic cross-sectional view of the vertical cavity surface emitting laser of Example 3 of the present invention taken along a direction perpendicular to the substrate thereof.

In FIG. 7, there are illustrated a substrate 701, a lower cavity reflector layer 702, a lower clad layer 703, an active layer 704, an oxide aperture layer center portion 705 and an oxide aperture layer 706.

Additionally, there are also illustrated an upper clad layer 707, an upper cavity reflector adjacent clad layer 708, an upper cavity reflector high refractive index layer 709, an upper cavity reflector low refractive index medium 710, an upper cavity reflector cap layer 711, a p-electrode 712 and an n-electrode 713.

The device of this example is identical with the first example sequentially from the substrate 701 up to upper cavity reflector adjacent clad layer 708 in term of the specific materials, the dimensions and the functions of these components of the device.

Therefore, only the differences between this example and Example 1 will be described below.

In this example, an upper cavity reflector cap layer 711 is laid on the upper cavity reflector high refractive index layer 709 (which is the photonic crystal reflector main body that is the upper cavity reflector).

Additionally, the medium of the upper cavity reflector cap layer is made to enter the holes of the photonic crystal reflector to produce the upper cavity reflector low refractive index medium 710.

The periodic structure of the photonic crystal reflector is the same as that of Example 1 and shows a rectangular lattice structure. The low refractive index medium shows a column structure extending in the direction perpendicular to the surface. However, since the low refractive index medium is not holes and one of the opposite sides of the reflector layer is not exposed to air but to the cap layer so that the effective refractive index differs at the opposite sides, the period of the photonic crystal and the diameter of the low refractive index medium differ.

In this example, since the low refractive index medium and the cap layer are ITO, the period of the photonic crystal and the diameter of the low refractive index medium are respectively 230 nm and 60 nm, the thickness thereof is 150 nm.

The photonic crystal is arranged in the entire region of the reflector surface and the area of the reflector is 20 um as in Example 2. Thus, the view of the laser device of this example as viewed in a direction perpendicular to the reflector surface is the same as FIG. 6B.

The upper cavity reflector cap layer is also made of ITO and has a thickness of 300 nm.

With the above-described arrangement, the device of this example shows a structure where the upper cavity reflector high refractive index medium (photonic crystal reflector) is buried in the ITO of the low refractive index medium.

Now, the electrode structure of this example will be described below.

The p-side electrode of this example is a ring-shaped electrode made of Ag. The p-side electrode is not formed directly on the upper cavity reflector but on the upper cavity reflector cap layer. The n-side electrode of this example is the same as that of Example 1 in terms of material and arrangement.

The method of manufacturing the device of this example is the same as that of Example 1 down to the step of forming the upper cavity reflector high refractive index layer.

Subsequently, in this example, ITO is sputtered on the high refractive index layer to bury the holes and form a film.

The final step of forming the p- and n-electrodes is the same as that of Example 1.

The differences of refractive index between the photonic crystal layer and the layers adjacent to the photonic crystal can be made more symmetric by sandwiching the photonic crystal between the upper and lower mediums showing the same refractive index.

Such an arrangement is advantageous for propagation of light in the inside of the photonic crystal reflector.

Since the upper surface of the reflector cap layer is made flat, it is easy to arrange an electrode on the front surface and provide an advantage for injecting an electric current.

While a ring-shaped electrode is used in this example, a rectangular or round electrode may be laid on a region including the light emitting section (the region immediately above the current confining structure and the surrounding region).

Such an arrangement is preferable because an electric current can be injected perpendicularly relative to the light emitting region of the active layer.

When such an arrangement is adopted, it is preferable to use a transparent electrode. Therefore, a preferable arrangement may be to operate the entire upper cavity reflector cap layer as electrode.

Of course, a separate transparent electrode may be formed on the cap layer. With the above-described arrangement of this example, it is possible to provide a larger reflector region for the photonic crystal reflector.

The larger is the area of the photonic crystal reflector, so is the smaller the leak of light in in-plane directions. Then, it is possible to improve the performance of the laser device.

Thus, the arrangement of this example can further improve the performance of a photonic crystal reflector.

### EXAMPLE 4

The vertical cavity surface emitting laser according to the present invention of Example 4 will be described below.

FIG. 8 is a schematic cross-sectional view of the vertical cavity surface emitting laser of Example 4 of the present invention taken along a direction perpendicular to the substrate thereof.

In FIG. 8, there are illustrated a substrate 801, a lower cavity reflector layer 802, a lower clad layer 803, an active layer 804, an oxide aperture layer center portion 805 and an oxide aperture layer 806.

Additionally, there are also illustrated an upper clad layer 807, an upper cavity reflector adjacent clad layer 808, an upper cavity first reflector high refractive index layer 809 and an upper cavity first reflector low refractive index medium 810.

Furthermore, there are illustrated an upper cavity reflector spacer layer 811, an upper cavity second reflector high refractive index layer 812, an upper cavity second reflector low refractive index medium 813, an upper cavity reflector cap layer 814, a p-electrode 815 and an n-electrode 816.

The components of the device of this example from the substrate 801 up to the upper cavity reflector adjacent clad layer 808 are identical with those of the Example 3 from the substrate 701 up to the upper cavity reflector adjacent clad layer 708.

Additionally, the n-electrode 816 is the same as the n-electrode 713 of Example 3.

The laser device of this example has a structure where another photonic crystal reflector is put on the upper cavity reflector of the device of Example 3 to produce two successive photonic crystal reflectors.

Now, the differences between this example and Example 3 will be described below.

As for the first photonic crystal reflector and the second photonic crystal reflector of this example, the high refractive index layers 809 and 812 are made of Al_{0.5}Ga_{0.5}As and the low refractive index mediums 810 and 813 are made of ITO as in Example 3.

Column structures of the low refractive index medium are arranged periodically in a high refractive index layer. The arrangement is realized in the form of rectangular lattice as in Example 3. The period and the column diameter are also the same as those of Example 3. The thickness of the reflector is the same as that of Example 3.

In this example, the first photonic crystal reflector and the second photonic crystal reflector are separated from each other by the upper cavity reflector spacer layer. The spacer layer is made of ITO, which is the material of the low refractive index mediums 810 and 813 of the photonic crystal reflectors, to produce a continuous structure.

In this example, the design of the spacer layer significantly affects the function of the upper cavity reflector. More specifically, each pair of a photonic crystal layer and a spacer layer is so designed that the phase of reflected light is advanced by (n/2) wavelengths in the pair.

The phase of light reflected by a photonic crystal reflector remains constant when reflected light is emitted from the photonic crystal.

Therefore, it is only necessary to adjust the thickness of the spacer layer so that the phase matching requirements may be satisfied by the two pairs. In this example, the spacer layer is made to have a thickness of 88 nm.

Now, the positional relationship of the photonic crystal reflectors that are the first and second cavity reflectors in in-plane directions will be described below.

In this embodiment, since the optical path length between the center lines of the planes is as short as a half of the wavelength, lights propagating through the adjacent photonic crystal reflectors of the cavity reflector layer in in-plane directions are coupled with each other.

Therefore, the characteristics of the single cavity reflector layer formed by two photonic crystal reflectors changes depending on the positional relationship in the in-plane directions of the two photonic crystal reflectors. Thus, it is necessary to keep the positional relationship constantly the same.

In this example, the two photonic crystal reflectors are positionally so arranged that the holes of the two reflectors are aligned as viewed in the direction perpendicular to the substrate.

The method of preparing the device of this example is the same as that of Example 3 except that a step of forming the first photonic crystal reflector is added to the latter method.

More specifically, after forming the upper cavity reflector adjacent clad layer, the first photonic crystal reflector and the second photonic crystal reflector are formed sequentially.

This can be done by repeating the steps from the step of forming the upper cavity reflector high refractive index medium to the step of forming the upper cavity reflector cap layer twice.

While two photonic crystal reflectors are put one on the other in the above description of this example, it is also possible to lay three, four or more than four photonic crystal reflectors one on the other.

Three or more than three photonic crystal reflectors can be laid one on the other by repeating the step of laying a photonic crystal reflector thrice or more than thrice.

It is possible to realize a large reflectivity that is greater than the reflectivity of any single photonic crystal reflector by laying a plurality of photonic crystal reflectors one on the other to form a single reflector as in this example.

Thus, if the reflectivity of any of the photonic crystal reflectors falls due to a manufacturing error, it can be compensated by the remaining photonic crystal reflector or reflectors.

### EXAMPLE 5

The vertical cavity surface emitting laser according to the present invention of Example 5 will be described below.

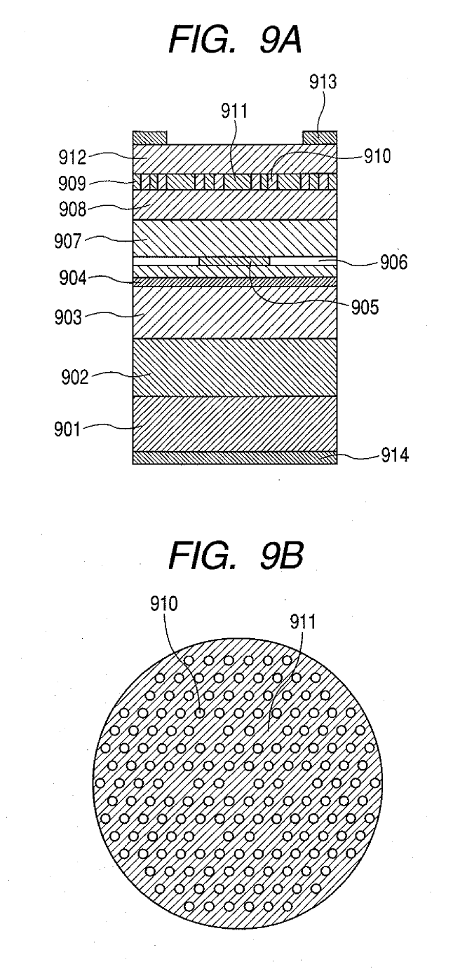

FIGS. 9A and 9B are schematic views illustrating the configuration of the vertical cavity surface emitting laser of Example 5.

FIG. 9A is a schematic cross-sectional view of the vertical cavity surface emitting laser of Example 5 taken along a direction perpendicular to the substrate thereof.

FIG. 9B is a schematic plan view of the upper cavity reflector of the vertical cavity surface emitting laser of Example 5 as viewed in a direction perpendicular to the reflector plane.

In FIGS. 9A and 9B, there are illustrated a substrate 901, a lower cavity reflector layer 902, a lower clad layer 903, an active layer 904, an oxide aperture layer center portion 905 and an oxide aperture layer 906.

Additionally, there are also illustrated an upper clad layer 907, an upper cavity reflector adjacent clad layer 908, an upper cavity reflector high refractive index layer 909 and an upper cavity reflector low refractive index medium 910.

Furthermore, there are illustrated an upper cavity reflector defect portion 911, an upper cavity reflector cap layer 912, a p-electrode 913 and an n-electrode 914.

The basic configuration of the device of this example is identical with that of the device of Example 3 except the components 909 through 911 that form the upper cavity reflector.

Therefore, only the upper cavity reflector of this example will be described below by referring to FIG. 9B.

As seen from FIG. 9B, of the upper cavity reflector of this example, the high refractive index layer 909 is made of Al_{0.5}Ga_{0.5}As and the lower refractive index medium 910 is made of ITO and column structures of the low refractive index medium are periodically arranged in the high refractive index layer as in Example 3.

Note, however, that the photonic crystal structure of this example is that of a triangular lattice so that a defect portion 911 having no low refractive index medium is arranged at every three periods. The reflector has a thickness of 150 nm as in Example 3 and the period and the diameter of the lattice are 200 nm and 60 nm respectively.

The defect portion is provided at only at the center with a diameter of 10 μm, whereas the total area of the reflector layer is 25 μmφ.

Although not clearly illustrated in FIG. 9B, the photonic crystal structure is formed with 125 periods, whereas the periodic defect structure is formed with a total of 17 periods because a period thereof corresponds to three periods of photonic crystal.

The method of manufacturing the device of this example is substantially the same as that of Example 3. The method differs from the latter only in that the defect portions are introduced when forming the photonic crystal pattern of the upper cavity reflector.

The defect portions can be introduced by following the steps of Example 3, only changing the EB lithography pattern when forming the photonic crystal pattern.

The function of the cavity reflector of this example will be described below.

A defect is introduced into the light emitting region of the cavity reflector of FIG. 9B at every three periods of holes of the photonic crystal.

Light produced by converting resonated light into in-plane guided mode that is localized in each defect of the photonic crystal is coupled with localized light in a guided mode in an adjacent defect.

In the surrounding region that is free from defects, the wavelength of oscillating light falls within the wavelength range of the photonic band gap of the photonic crystal. Therefore, oscillating light cannot propagate through such region. Thus, a laser beam is irradiated only from the center region where defects are provided and it is possible to prevent light from leaking in in-plane directions of the cavity reflector. Additionally, it is possible to control the profile and the size of the spot of oscillating light by controlling the manner of introducing defects.

While defects are introduced at a period as large as the three fundamental periods of the photonic crystal in this example, the defects can be introduced at other period.

Additionally, it is not necessary that defects appear periodically and they may alternatively appear non-periodically. In any case, defects need to be separated from each other by a distance that allows lights localized in defects to be coupled with each other. In this example, the distance is preferably not smaller than two periods and not greater than ten periods.

While the defects are formed by removing some of the columns of the low refractive index medium in the upper cavity reflector in this example, defects can alternatively be formed by differentiating the diameters of the holes of the photonic crystal from the original diameter to have a large diameter and a small diameter.

### EXAMPLE 6

The vertical cavity surface emitting laser according to the present invention of Example 6 will be described below.

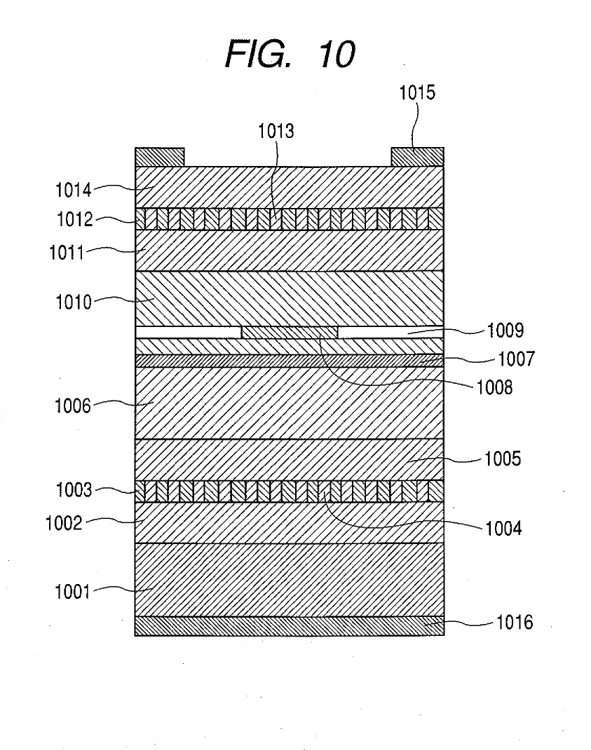

FIG. 10 is a schematic cross-sectional view of the vertical cavity surface emitting laser of Example 6 of the present invention taken along a direction perpendicular to the substrate thereof.

In FIG. 10, there are illustrated a substrate 1001, a lower cavity reflector light confinement layer 1002, a lower cavity reflector high refractive index layer 1003 and a lower cavity reflector low refractive index medium 1004.

Additionally, there are also illustrated a lower cavity reflector adjacent clad layer 1005, a lower clad layer 1006, an active layer 1007, an oxide aperture layer center portion 1008, an oxide aperture layer 1009, an upper clad layer 1010 and an upper cavity reflector adjacent clad layer 1011. Furthermore, there are illustrated an upper cavity reflector high refractive index layer 1012, an upper cavity reflector low refractive index medium 1013, an upper cavity reflector cap layer 1014, a p-electrode 1015 and an n-electrode 1016.

The substrate 1001, the n-electrode 1016 and the layers from the active layer 1007 to the p-electrode 1015 are the same as the substrate 701, the n-electrode 713 and the layers from the lower clad layer 703 to the p-electrode 712 of Example 3.

Only the differences between this example and Example 3 will be described below.

In this example, the lower cavity reflector is not a DBR but a photonic crystal reflector.

The lower cavity reflector high refractive index layer 1003 and the lower cavity reflector low refractive index medium 1004 of the reflector are the same as the upper cavity reflector in terms of material, configuration and dimensions. Additionally, in this example, the lower cavity reflector is sandwiched between the lower cavity reflector light confinement layer 1002 and the lower cavity reflector adjacent clad layer 1005. Each of these layers is made of ITO and the two layers have the same thickness of 300 nm. The thickness of the lower clad layer is 465 nm which is smaller than the thickness of the lower clad layer of Example 3 because the lower cavity reflector adjacent clad layer is provided.

The cavity reflector length of this example also corresponds to 6.5 wavelengths.

Now, the positional relationship of the two photonic crystal reflectors will be described below.

Since the cavity reflector length of this example is as long as 6.5 times of the wavelength, two lights propagating in in-plane directions in the two reflectors are not coupled with each other.

Therefore, the two reflectors can take any positional relationship in in-plane directions.

As for the direction of rotation, the photonic crystal of this example shows a rectangular lattice and does not depend on polarization so that the two reflectors can take any positional relationship in the direction of rotation. However, it is preferable that the two reflectors show a constant positional relationship.

When the distance separating the two reflectors is short and propagating lights are coupled with each other, it is necessary as described in Example 4 that the two reflectors show a constant positional relationship both in in-plane directions and in the direction of rotation.

Now, the method of manufacturing the device of this example will be described below.

Firstly, the layers from the lower clad layer 1006 to the upper cavity reflector adjacent clad layer 1011 are formed on the GaAs substrate. Subsequently, the photonic crystal reflector formed on another substrate is bonded to the upper cavity reflector adjacent clad layer 1011.

The manufacturing method of this example is the same as that of Example 3 down to this step. However, in this example, the bonded latter substrate is not removed but the original substrate is removed typically by CMP.

After removing the original substrate, an ITO layer is formed as the lower cavity reflector adjacent clad layer by sputtering.

Then, another photonic crystal reflector prepared on still another substrate is bonded and, this time, the GaAs substrate is removed typically by CMP.

Thereafter, the lower cavity reflector light confinement layer is formed on the surface that appears as a result of removing the substrate and then another GaAs substrate is bonded.

Subsequently, the GaAs substrate at the upper cavity reflector side is removed and the upper cavity reflector cap layer is formed as in Example 3.

Finally, the p- and n-electrodes are formed. The device of this example where both the upper and lower cavity reflectors are photonic crystal reflectors is advantageous for realizing a surface light emitting laser by means of materials such as GaN/AlN type materials and InGaAsP type materials by which it is difficult to prepare a DBR.

Additionally, if an AlGaAs type material is used, it is possible to improve the heat discharging efficiency because a DBR can be formed without forming a large number of layers.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-053850, filed Feb. 28, 2006, which is hereby incorporated by reference herein in its entirety.

What is claimed is:

1. A vertical cavity surface emitting laser comprising a cavity formed by arranging a first reflector, an active region and a second reflector on a substrate;
the second reflector being formed to include a refractive index periodic structure having a first medium showing a first refractive index and a second medium showing a second refractive index lower than the first refractive index, the first medium and the second medium being arranged periodically in an in-plane direction of the substrate;
an electrically conductive adjacent layer made of a material showing a refractive index lower than the first refractive index being arranged at a position adjacent to the second reflector between the active region and the second reflector.

2. The laser according to claim 1, wherein
the material of the adjacent layer is an electrically conductive material showing a refractive index lower than the first medium of the refractive index periodic structure by more than 10%.

3. The laser according to claim 1, wherein
the adjacent layer has such an electric conductivity that an electric current can be injected in the active region immediately below the refractive index periodic structure by way of the adjacent layer.

4. The laser according to claim 1, wherein
at least one of the reflectors that define the cavity is formed by laying a plurality of layers each having a periodic structure in an in-plane direction and an adjacent layer is arranged adjacent to each of those layers.

5. The laser according to claim 1, wherein
one of the reflectors that define the cavity is a distributed Bragg reflector and the other is a one-dimensional or two-dimensional photonic crystal having a periodic structure.

6. The laser according to claim 1, wherein
both of the pair of reflectors that define the cavity are one-dimensional or two-dimensional photonic crystals having a periodic structure.

7. The laser according to claim 1, wherein
the periodic structure is covered by an electrically conductive medium showing a refractive index lower than the first medium showing the first refractive index of the periodic structure by not less than 10%.

8. The laser according to claim 1, wherein
the first medium showing the first refractive index of the periodic structure is a dielectric.

9. The laser according to claim 1, wherein
the first medium showing the first refractive index of the periodic structure is a semiconductor.

10. The laser according to claim 1, wherein
a site that disturbs the periodicity of the periodic structure is arranged in the periodic structure periodically or non-periodically.

11. The laser according to claim 1, wherein
the adjacent layer functions as current injection channel at the same time as confining light in the periodic structure.
